(19) United States
(12) Patent Application Publication
(10) Pub. No.: US 2023/0048439 A1
(43) Pub. Date: Feb. 16, 2023

(54) VARIABLE AREA VACUUM CHUCK SYSTEM AND METHOD FOR OPERATING SAME

(71) Applicant: IO Tech Group Ltd., London (GB)

(72) Inventors: Ziv Gilan, Kfar-harif (IL); Moshe Koko Havive, Nes Ziona (IL); Guy Nesher, Nes Ziona (IL); Daniel Liptz, Jerusalem (IL); Rachel Krause, Rishon Le Zion (IL)

(21) Appl. No.: 17/401,617

(22) Filed: Aug. 13, 2021

(51) Int. Cl. B25J 15/06; B25J 15/00

(52) U.S. Cl. CPC B25J 15/0658; B25J 15/0683; B25J 15/0061; B65G 47/91

(57) ABSTRACT

A vacuum chuck system may include a vacuum chuck and a vacuum stopper collection and dispensing system. The vacuum chuck may include a ceramic plate with a retaining surface. The retaining surface may include a plurality of depressions and a plurality of openings, each of the openings being disposed on a bottom surface of one of the depressions and fluidly coupled to a vacuum pump. Vacuum stoppers may be used to seal one or more of the openings so as to restrict the vacuum area of the vacuum chuck. The vacuum stopper collection and dispensing system may be used to collect vacuum stoppers from and dispense vacuum stoppers onto the retaining surface. In addition or in the alternative, an electromagnet or a robotic arm may be used to move a vacuum stopper from a blocking position to a non-blocking position on the retaining surface.

### FIELD OF THE INVENTION

The present invention relates to a vacuum chuck system for holding a component (e.g., a board), and more specifically relates to a vacuum chuck with a retaining surface for which the “vacuum area” (or an extent of the retaining surface with a pressure below atmospheric pressure) can be changed by the addition or removal of vacuum stoppers.

### BACKGROUND

Vacuum chucks are used above all in the wood, plastics and non-ferrous metals industries for quick, simple machining. They are compatible with computer numerical control (CNC) machine tools. The latest vacuum chucks allow attachments of various sizes and shapes to be exchanged in a very short amount of time, thus facilitating flexible handling of a wide range of workpiece shapes.

In vacuum chucks, a sub-atmospheric pressure is generated under the workpiece being clamped (i.e., a pressure differential is created which presses the workpiece against the clamping plate). Thus, the workpiece is pressed against the clamping plate of the vacuum chuck. The holding force of the workpiece depends on its surface structure, the pressure differential and the area on which the vacuum acts. The larger this area is, the better the holding forces.

In printed circuit (PC) board manufacturing, often times a vacuum chuck is used to move the PC board from place to place without any relative movement between the vacuum chuck and the PC board. The use of the vacuum clamping is essential when mechanical force is applied on the PC board in use and whenever movement of the PC board is involved.

Although very important for PC board manufacturing, the vacuum chuck has a limiting disadvantage, since its structure cannot be easily changed. As a result, the design of the vacuum area of the vacuum chuck must match specifically the footprint of the PC board that one wants to hold during fabrication. However, the dimension of boards may change from application to application, while the vacuum area stays unchanged.

There are several approaches to overcome this challenge. One way is to change the vacuum plate (i.e., the top plate) of the chuck each time the PC board size is changed. However, this approach is possible only when there are a very small number of boards that are used in the machine, for example in a production machine. However, in a machine that is used for boards of various sizes, the user must have possession of many vacuum plates with different dimensions which is space consuming.

Therefore, the existing solutions are not efficient enough and are not flexible enough for machines where board sizes are changing at high rate.

### SUMMARY OF THE INVENTION

One important aspect of the vacuum chuck according to the present invention is the ability to change the vacuum area of the vacuum chuck to match the footprint of a board in an automated way without any extended downtime and without changing the original vacuum plate (i.e., the top plate) of the vacuum chuck.

The present invention is based in part on the surface structure of the vacuum plate which permits the vacuum area to be adapted to components with various sized/shaped footprints. The surface of the vacuum plate is constructed with depressions, typically in the form of straight-line segments. Each depression has an opening that can be unsealed or sealed by a vacuum stopper and in such way, the vacuum area of the vacuum chuck can be changed. The vacuum stoppers can be incorporated within the vacuum plate itself or be dispensed from and collected within a magazine external to the vacuum plate.

The vacuum chuck may have pins that can place and lift the board and those pins also allow the user to replace one board with another board.

These and other embodiments of the invention are more fully described in association with the drawings below.

### BRIEF DESCRIPTION OF THE DRAWINGS

The present invention illustrated by way of example, and not limitation, in the figures of the accompanying drawings, in which:

FIG. 1a depicts a top view of a vacuum chuck, in accordance with one embodiment of the present invention.

FIG. 1b depicts a perspective cross-sectional view of the vacuum chuck along line I-I of FIG. 1a, in accordance with one embodiment of the present invention.

FIG. 1c depicts a perspective cross-sectional view of the vacuum chuck along line II-II of FIG. 1a, in accordance with one embodiment of the present invention.

FIG. 1d depicts a perspective cross-sectional view of the vacuum chuck along line VI-VI of FIG. 1a, in accordance with one embodiment of the present invention.

FIG. 1e depicts a side view of the vacuum chuck, in accordance with one embodiment of the present invention.

FIG. 1f depicts a perspective view of the vacuum chuck in which lift pins are visible, in accordance with one embodiment of the present invention.

FIG. 2 depicts a top view of a top holder plate with a plurality of through holes, in accordance with one embodiment of the present invention.

FIG. 3 depicts a top view of a top rubber layer with a plurality of through holes, in accordance with one embodiment of the present invention.

FIG. 4 depicts a cross section of the vacuum distribution plate along line of FIG. 1d, in accordance with one embodiment of the present invention.

FIG. 5 depicts a top view of a bottom rubber layer with a plurality of through holes that are fluidly connected to the vacuum pump, in accordance with one embodiment of the present invention.

FIG. 6 depicts a top view of a bottom holder plate with a plurality of through holes, in accordance with one embodiment of the present invention.

FIG. 7 depicts a zoomed-in portion of the vacuum chuck labeled as IV in FIG. 1c, in accordance with one embodiment of the present invention.

FIG. 8a depicts a side perspective view of a component placing module in which the component support member is located in a retracted position, in accordance with one embodiment of the present invention.

FIG. 8b depicts a top perspective view of a component placing module in which the component support member is located in a retracted position, in accordance with one embodiment of the present invention.

FIG. 8c depicts a top perspective view of a component placing module in which the component support member is located in an extended position, in accordance with one embodiment of the present invention.

FIG. 9a depicts a vacuum stopper collection and dispensing module configured in the collection mode, in accordance with one embodiment of the present invention.

FIGS. 9b-9d depict a vacuum stopper collection and dispensing module configured in the dispensing mode, in accordance with one embodiment of the present invention.

FIGS. 10a-10c depict a sequence of views illustrating a process of restricting the vacuum area of the retaining surface in order to secure a printed circuit (PC) board with more limited dimensions to the retaining surface, in accordance with one embodiment of the present invention.

FIGS. 11a-11b depict a sequence of views illustrating a process of increasing the vacuum area of the retaining surface in order to secure a PC board with larger dimensions to the retaining surface, in accordance with one embodiment of the present invention.

FIGS. 12a-12d depict a sequence of views in which a vacuum stopper is moved from a first to a second position in a depression by an electromagnet, in accordance with one embodiment of the present invention.

FIGS. 13a-13b depict a sequence of views in which a vacuum stopper is moved from a first to a second position in a depression by a robotic arm, in accordance with one embodiment of the present invention.

FIGS. 14a-14c depict the operation of a lever mechanism for controllably sealing or unsealing an opening of the retaining surface, in accordance with one embodiment of the present invention.

FIGS. 15a-15c depict the operation of a diaphragm mechanism for controllably sealing or unsealing an opening of the retaining surface, in accordance with one embodiment of the present invention.

FIGS. 16a-16c depict the operation of a spring-loaded ball mechanism for controllably sealing or unsealing an opening of the retaining surface, in accordance with one embodiment of the present invention.

FIG. 17a-17c depict various arrangements of depressions on the retaining surface of a vacuum chuck, in accordance with one embodiment of the present invention.

FIG. 18 depicts components of a computer system in which computer readable instructions instantiating the methods of the present invention may be stored and executed.

### DETAILED DESCRIPTION

In the following detailed description of the preferred embodiments, reference is made to the accompanying drawings that form a part hereof, and in which are shown by way of illustration specific embodiments in which the invention may be practiced. It is understood that other embodiments may be utilized and structural changes may be made without departing from the scope of the present invention. Descriptions associated with any one of the figures may be applied to different figures containing like or similar components.

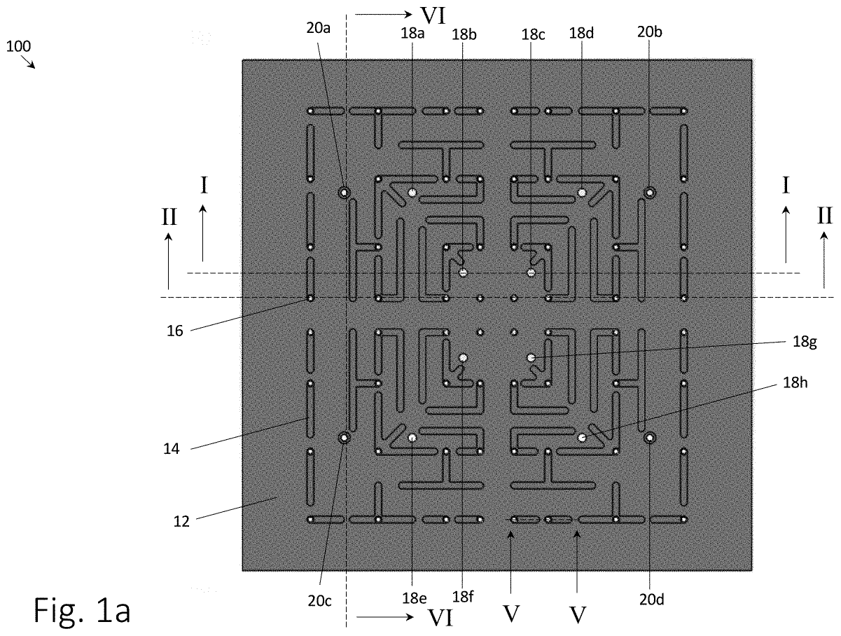

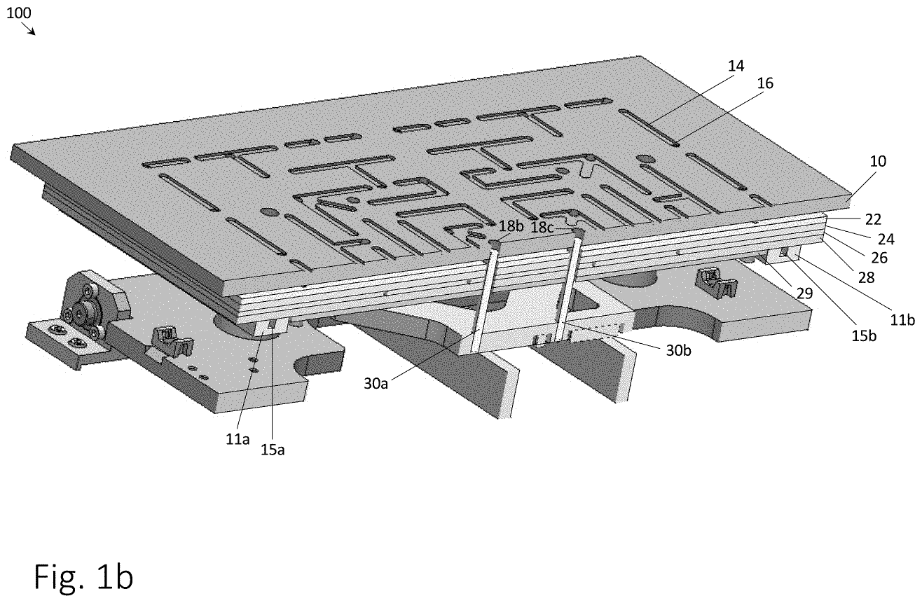

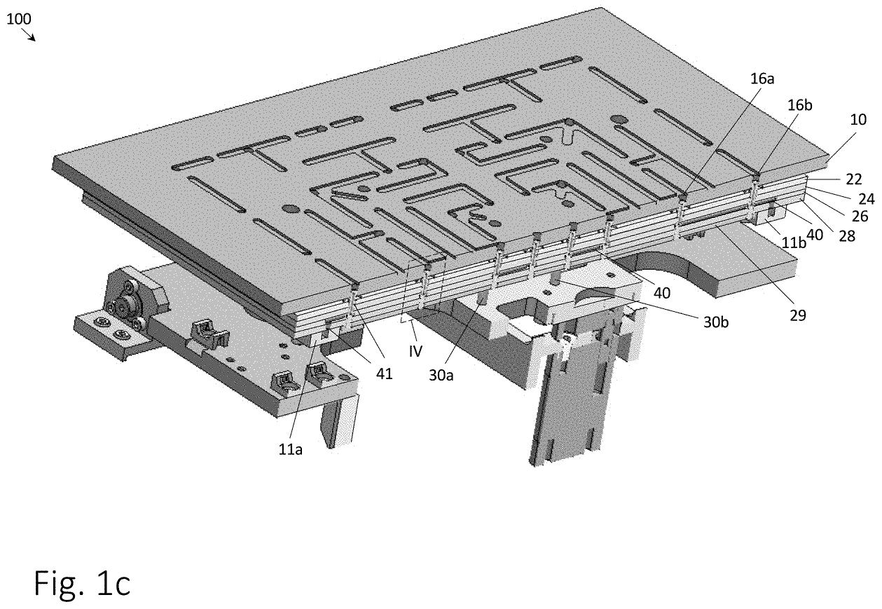

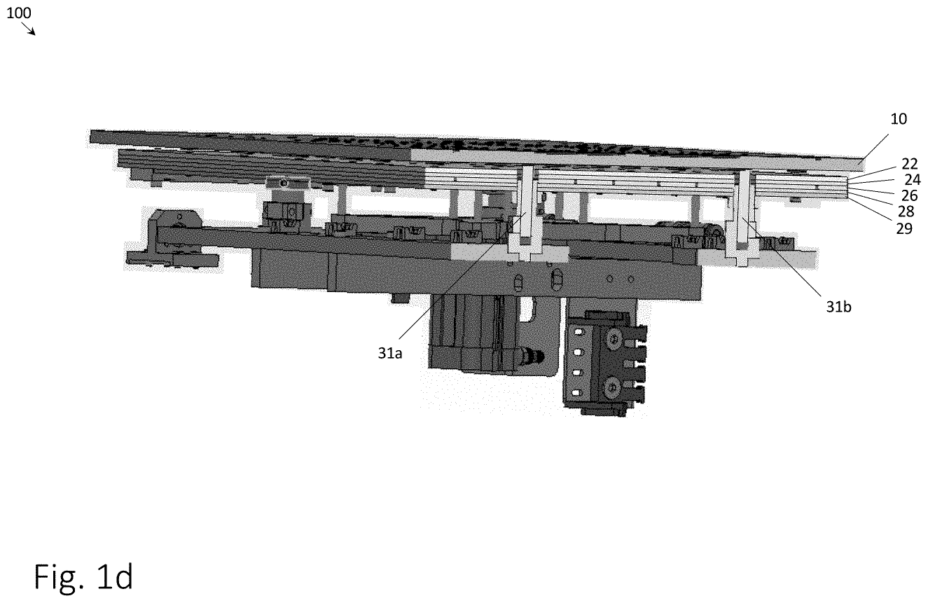

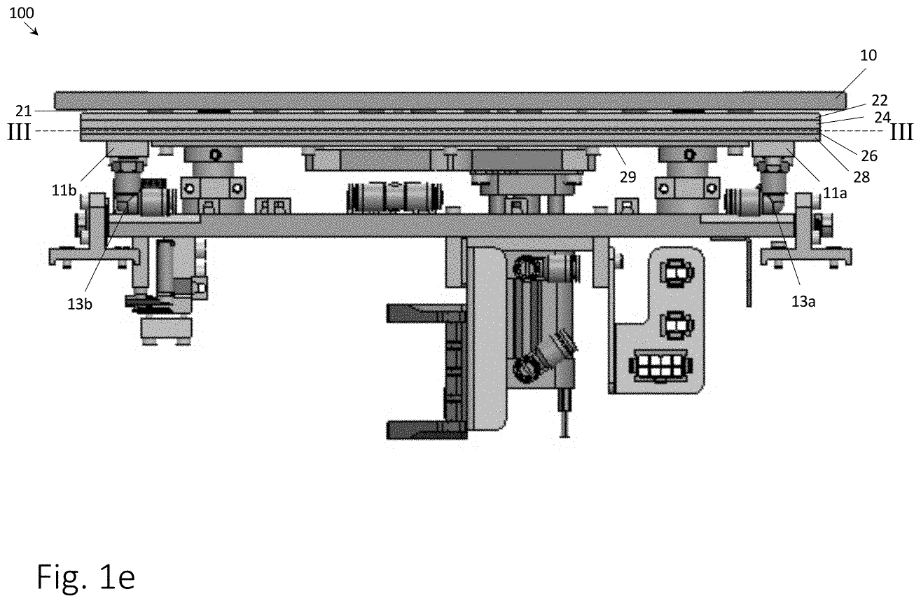

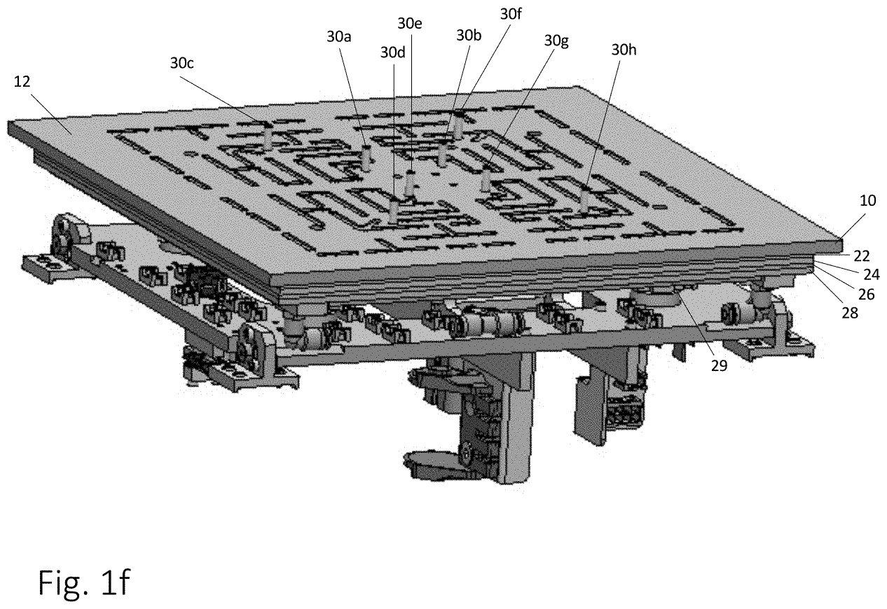

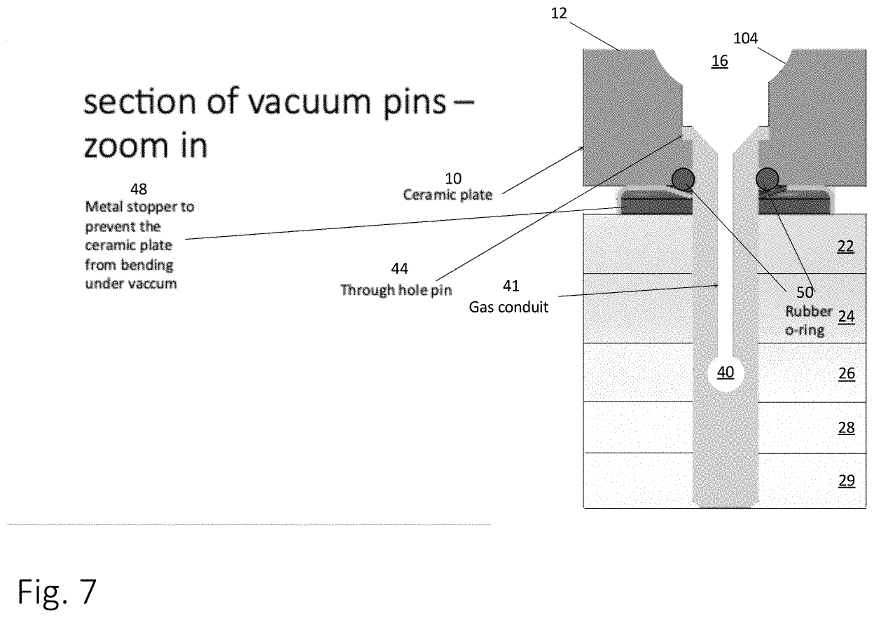

FIG. 1a depicts a top view of the vacuum chuck 100 in which the ceramic plate 10 is visible. The top surface 12 of the ceramic plate 10 may, at times, be called a retaining surface as it is a surface on which components (e.g., boards, etc.) are retained. The retaining surface 12 may include a plurality of depressions (one of which is labeled as 14) and plurality of vacuum-providing openings (one of which is labeled as 16). Each of the vacuum-providing openings 16 may be disposed on a bottom surface of one of the depressions 14. Other types of openings may be present, including openings 18a-18h for lift pins (visible in FIGS. 1B and 7) that protrude from the retaining surface 12, and openings 20a-20d for engaging with the ceramic plate adjustment pins (depicted in FIG. 1d). Each of the ceramic plate adjustment pins has a diameter that is larger than that of openings 20a-20d, so these pins do not penetrate through the ceramic plate 10 or protrude from the retraining surface 12.

In one embodiment, the retaining surface 12 has a flat profile (i.e., when viewed from the side, the retaining surface 12 will resemble a straight line). The depressions 14 of the retaining surface 12 help to distribute the vacuum from the vacuum-providing openings 16 over a larger area of the retaining surface 12. Typically, the depressions are in the form of line segments (i.e., to match the rectilinear profile of the components retained thereon), but it is also possible for the depressions to include curved portions.

The structure of the depressions 14 is important because in order to maintain a vacuum, each depression 14 must be completely covered by a surface of the component secured to the retaining surface 12. If one or more of the depressions 14 are not covered or are not covered completely, it will be difficult to maintain the vacuum of the vacuum chuck 100. Therefore, a small number of longer depressions will limit the use of the vacuum chuck 100 to secure components with a specific size. On the other hand, a large number of small depressions will allow components of various sizes to be secured to the vacuum chuck, with the tradeoff of a larger number of vacuum stoppers that potentially would be needed to restrict the vacuum area to match smaller sized components.

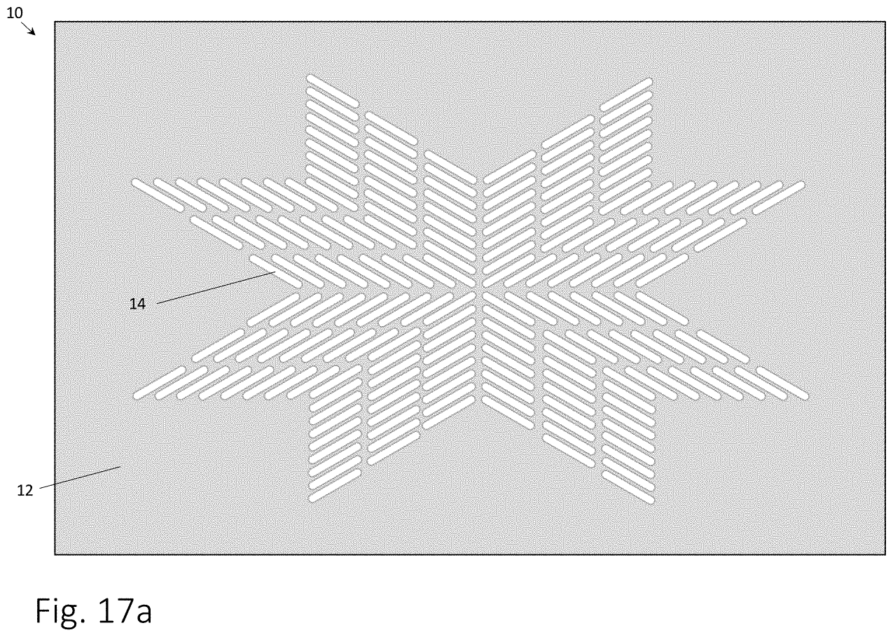

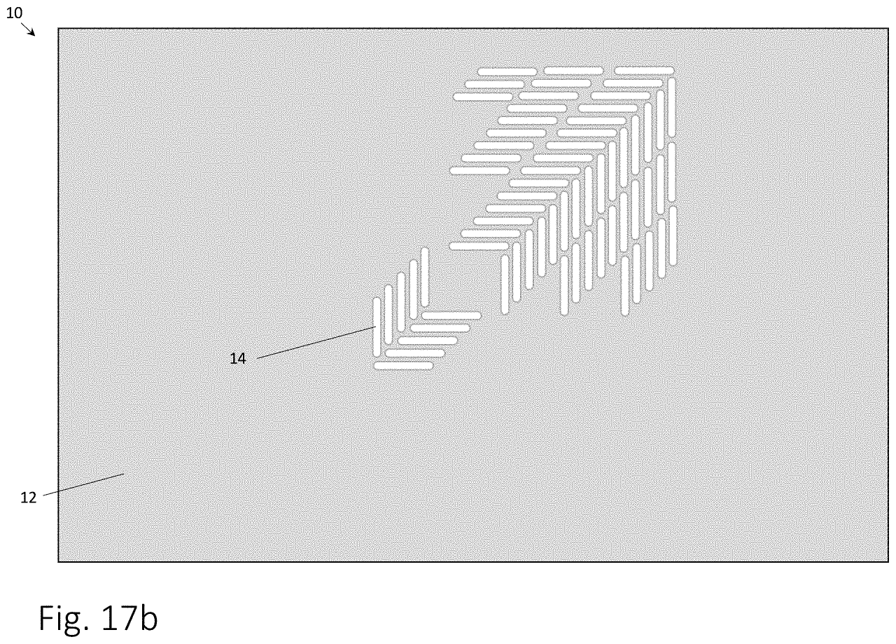

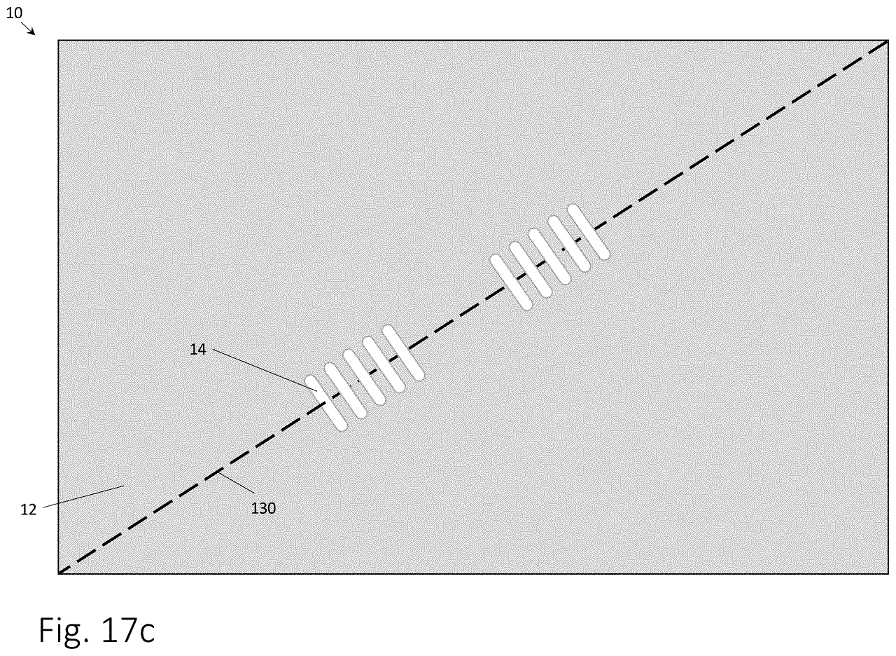

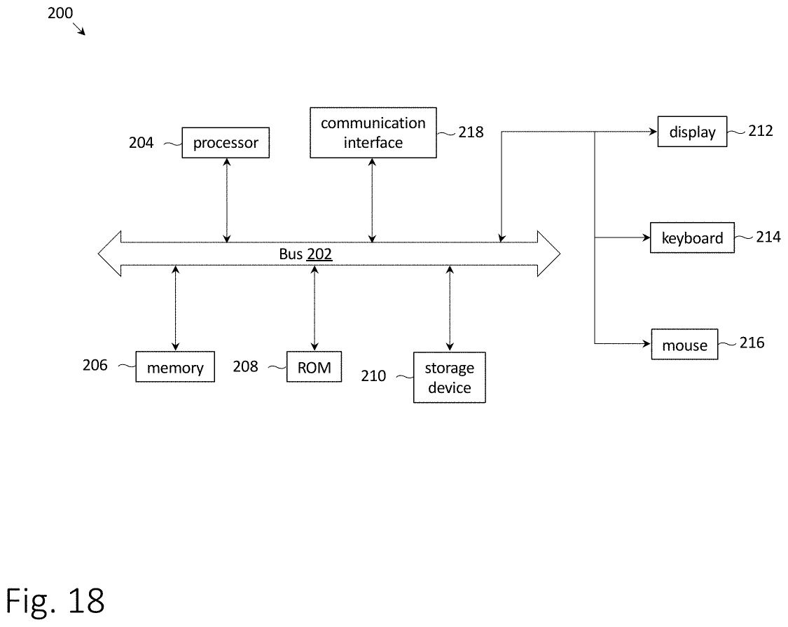

FIG. 1a illustrates a retaining surface 12 with a good compromise between the number of depressions 14, as well as the size and shape of each of the depressions 14. The number of vacuum-providing openings 16 is not too large, and the arrangement of depressions 14 enables components with various sizes to be secured to the retaining surface 12. However, it is understood that the arrangement of depressions 14 is not limited to the embodiment of FIG. 1a, and other arrangements are possible, including those depicted in FIGS. 17a-17c. FIG. 17a illustrates depressions that extend along the diagonals of the retaining surface 12 (one of which is labeled as 14). Such an arrangement enables a significant portion of the area beneath components of various sizes to be in contact with the vacuum. FIG. 17b illustrates depressions in a frame-like arrangement (one of which is labeled as 14), and FIG. 17c illustrates depressions (one of which is labeled as 14) that are oriented to be perpendicular to an imaginary diagonal line 130 drawn on the retaining surface 12.

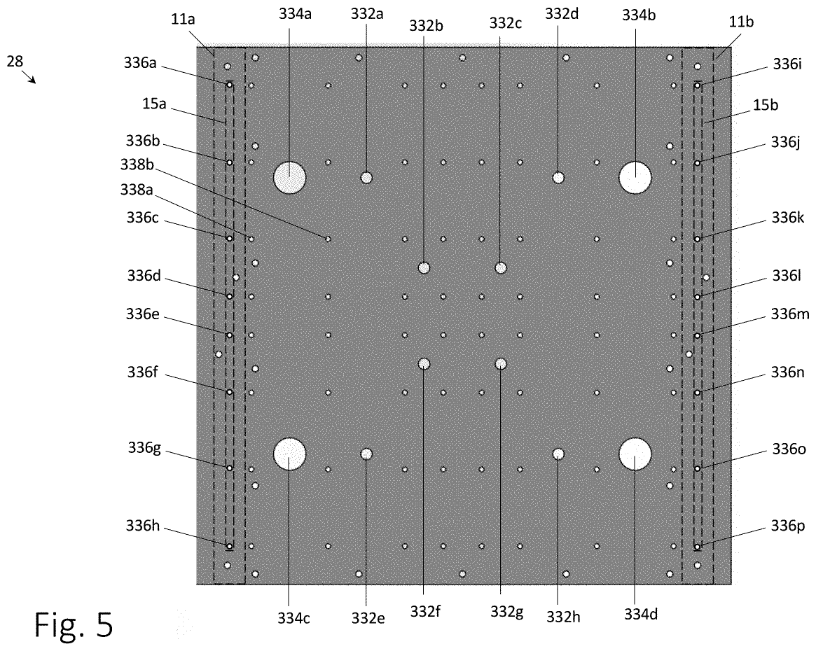

FIG. 1b depicts a perspective cross-sectional view of the vacuum chuck 100 along line I-I of FIG. 1a. In the cross-sectional plane, six layers of the vacuum chuck 100 are visible. The six layers include the previously described ceramic plate 10, a top holder plate 22, a top rubber layer 24, a vacuum distribution plate 26, a bottom rubber layer 28 and a bottom holder plate 29. While not clearly depicted in FIG. 1b (and more clearly understood from FIG. 7), a gap may be present between the ceramic plate 10 and the top holder plate 22 due to the presence of metal stoppers 48 between these plates (one of which is illustrated in FIG. 7). In the cross-sectional plane, tunnel members 11a, 11b are also visible. Tunnel members 11a, 11b each have a gas channel 15a, 15b that connect gas outlets of the six layer assembly to a vacuum pump (not depicted). The configuration of the tunnel members 11a, 11b with respect to the gas outlets will be more clearly understood in FIG. 5.

The vacuum distribution plate 26 is typically a metal layer with gas distribution channels that evenly distribute the vacuum to different areas of the retaining surface 12. The vacuum distribution plate 26 provides rigidity to counteract the bending of the vacuum chuck 100 caused by the applied vacuum. The thickness of the ceramic plate 10 is also an important parameter for the same reason. The vacuum distribution plate 26 may be sandwiched on both sides by rubber layers 24, 28. Top rubber layer 24 acts as a seal between the top holder plate 22 and the vacuum distribution plate 26. Similarly, bottom rubber layer 28 acts as a seal between the vacuum distribution plate 26 and the bottom holder plate 29. Both rubber layers 24, 28 may also act as dampeners to overcome the brittleness of the ceramic plate 10.

FIG. 1c depicts a perspective cross-sectional view of the vacuum chuck 100 along line II-II of FIG. 1a. As visible in the cross-sectional plane, various paths are present for propagating the vacuum from the bottom rubber layer 28 to the ceramic plate 10. The paths may include vertical paths 41 that are connected to horizontal paths 40 of the vacuum distribution plate 26. The paths may also be called gas passageways or gas conduits. Multiple vacuum-providing openings (e.g., 16a, 16b) may be coupled to the same gas passageway. A vacuum stopper (as shown in later figures) can be positioned over a vacuum-providing opening to eliminate suction in certain portion of the retaining surface 12.

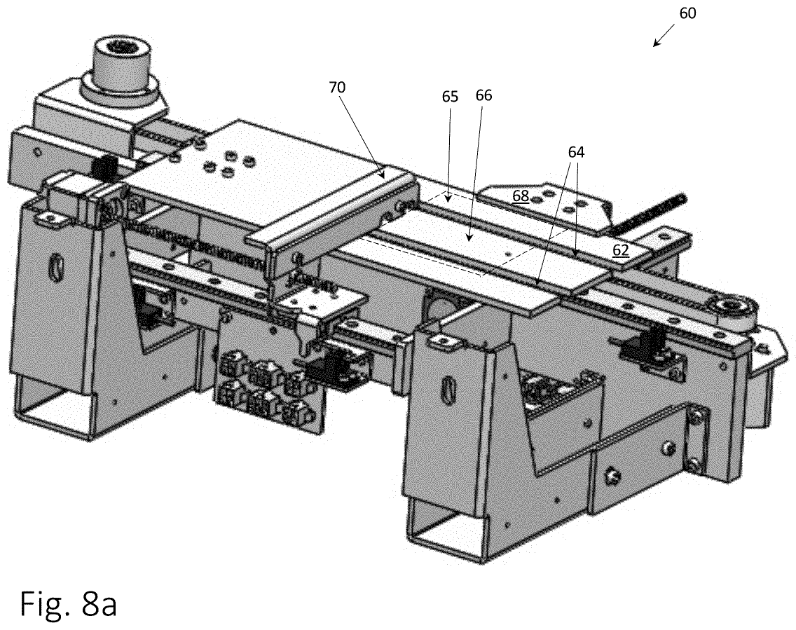

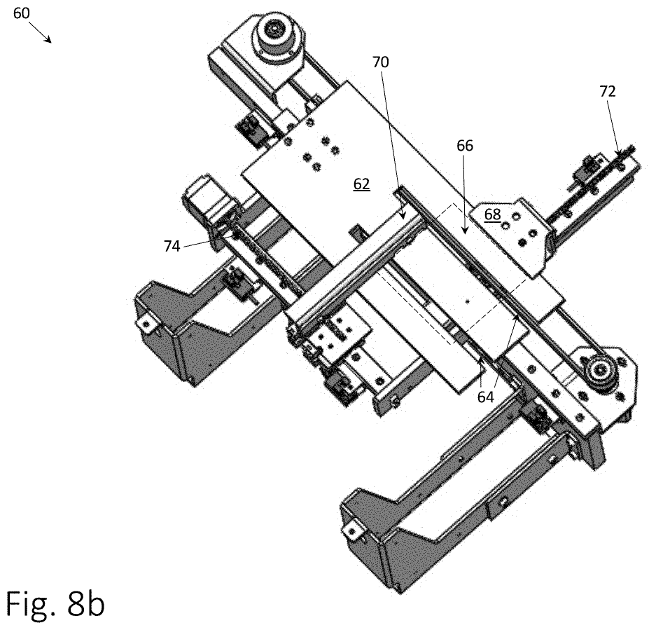

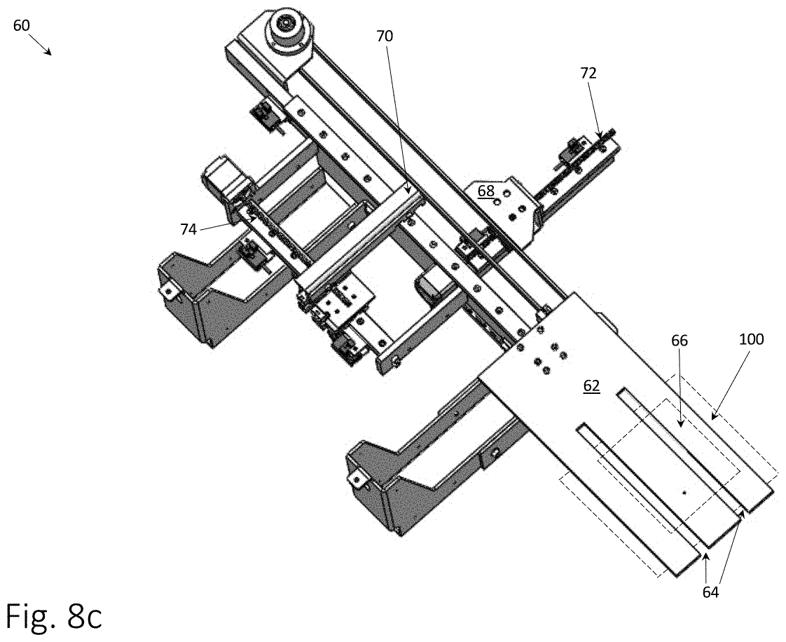

Also visible in FIG. 1c are two lift pins 30a, 30b, shown in a retracted position. In the retracted position, a component may rest against and be secured to the retaining surface 12. In an extended position, the lift pins lift the component from the retaining surface 12, allowing a component support member of a component placing module (depicted in FIGS. 8a-8c) to be inserted between the component and the retaining surface so as to remove the component from the vacuum chuck 100.

FIG. 1d depicts a perspective cross-sectional view of the vacuum chuck 100 along line VI-VI of FIG. 1a. Ceramic plate adjustment pins 31a, 31b are visible in the cross-sectional plane. These pins along with two other adjustment pins (not depicted) abut the bottom surface of the ceramic plate 10. By adjusting the vertical elevation of the ceramic plate adjustment pins, the orientation (e.g., tilt) of the ceramic plate 10 with respect to the other plates and layers may be adjusted.

FIG. 1e depicts a side view of the vacuum chuck 100. The six previously described layers of the vacuum chuck 100 are visible in the side view, along with the gap 21 between the ceramic plate 10 and the top holder plate 22. As shown, tunnel member 11a is disposed between the bottom rubber layer 28 and gas conduit 13a. Similarly, tunnel member 11b is disposed between the bottom rubber layer 28 and gas conduit 13b. Gas conduits 13a, 13b are each fluidly coupled to the vacuum pump (not depicted).

FIG. 1f depicts a perspective view of the vacuum chuck 100 in which lift pins 30a-30h are shown in an extended position. It is understood that the lift pins 30a-30h may translate in the vertical direction between such extended position and a retracted position, in which the top of the lift pins 30a-30h are level with or are below the retaining surface 12. While eight lift pins are depicted in the embodiment of FIG. 7, it is understood that a greater or fewer number of lift pins are possible in other embodiments. The surfaces that make up the through holes that house the lift pins 30a-30h are sealed so that no vacuum leaks through the through holes.

In operation, when a new component is ready to be placed on the vacuum chuck 100, the lift pins 30a-30h are first translated into an extended position. The component is then placed on top of one or more of the lift pins 30a-30h and the lift pins 30a-30h are translated in the downward (z-direction) direction while a vacuum is applied to the vacuum-providing openings 16. Once the component contacts the retaining surface 12, the vacuum chuck 100 holds the component, with the position of the component substantially fixed with respect to the retaining surface 12, until the vacuum is not applied anymore. When the component is ready to be removed from the vacuum chuck 100, the vacuum is stopped, and the lift pins 30a-30h are translated in the upward (z-direction) direction. The component is elevated above the retaining surface 12 by the lift pins 30a-30h in order to allow a component support member to be inserted underneath the component.

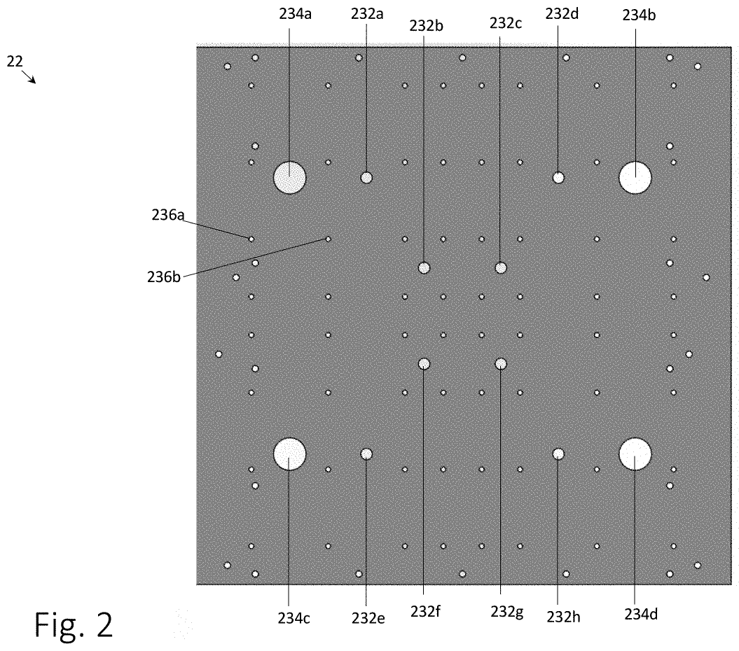

FIG. 2 depicts a top view of the top holder plate 22. The top holder plate 22, may have a plurality of holes, including holes (two of which are labeled as 236a, 236b) to accommodate the through hole pins. As more clearly understood from FIG. 7, the through hole pins may allow the passage of vacuum from the vacuum distribution plate 26 to the vacuum-providing openings 16 of the ceramic plate 10. The plurality of holes may also include holes (eight of which are labeled as 232a-232h) to accommodate the lift pins. The plurality of holes may also include holes (four of which are labeled as 234a-234d) to accommodate the ceramic plate adjustment pins.

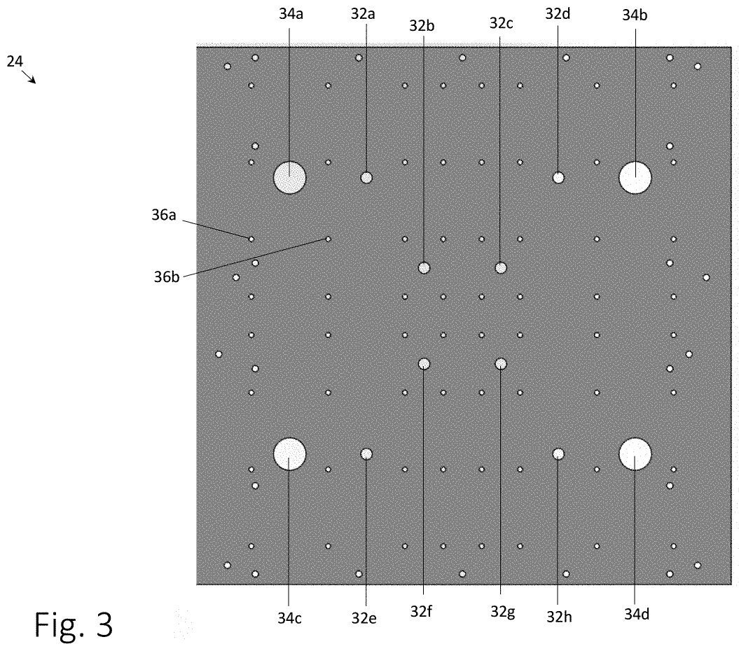

FIG. 3 depicts a top view of the top rubber layer 24. The top rubber layer 24, which in some cases could be a rubber-coated metal, plastic, or other plate, may have a plurality of holes, including holes (two of which are labeled as 36a, 36b) to accommodate the through hole pins. The plurality of holes may also include holes (eight of which are labeled as 32a-32h) to accommodate the lift pins. The plurality of holes may also include holes (four of which are labeled as 34a-34d) to accommodate the ceramic plate adjustment pins.

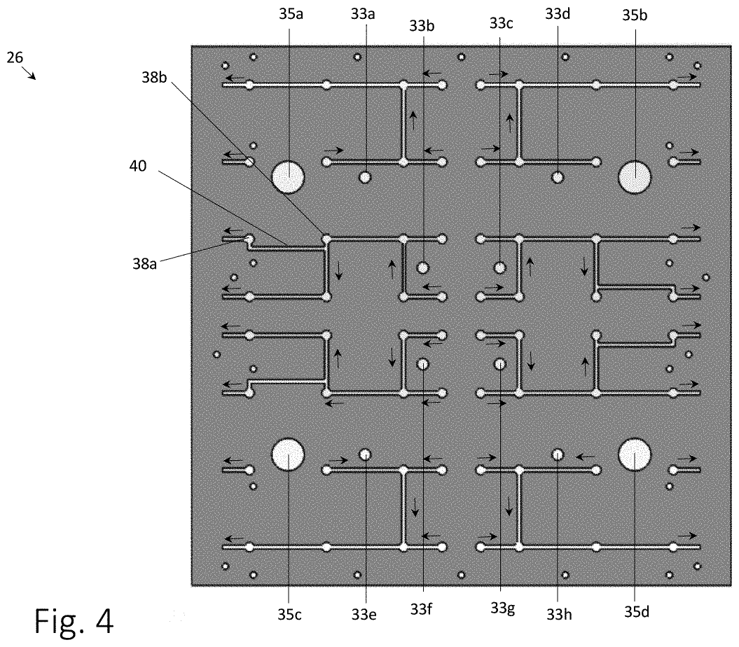

FIG. 4 depicts a cross section of the vacuum distribution plate 26 along line III-III of FIG. 1e. Vacuum distribution plate 26 may have a plurality of holes, including holes (two of which are labeled as 38a, 38b) to accommodate the through hole pins. The plurality of holes may also include holes (eight of which are labeled as 33a-33h) to accommodate the lift pins. The plurality of holes may also include holes (four of which are labeled as 35a-35d) to accommodate the ceramic plate adjustment pins. Horizontal gas passageways 40 may connect two or more of the holes (e.g., 38a, 38b) in order to distribute the vacuum over the retaining surface 12. A plurality of arrows indicates the direction of gas flow when the vacuum pump (not depicted) is in operation.

FIG. 5 depicts a top view of the bottom rubber layer 28. Bottom rubber layer 28, which in some cases could be a rubber-coated metal, plastic, or other plate, may have a plurality of holes, including holes (two of which are labeled as 338a, 338b) to accommodate the through hole pins. The plurality of holes may also include holes (eight of which are labeled as 332a-332h) to accommodate the lift pins. The plurality of holes may also include holes (four of which are labeled as 334a-334d) to accommodate the ceramic plate adjustment pins. In contrast to the top rubber layer 24, the bottom rubber layer 28 may also include holes (sixteen of which are labeled as 336a-336p) that fluidly couple the horizontal gas passageways 40 of the vacuum distribution plate 26 to the gas channels 15a, 15b of the tunnel members 11a, 11b. As all of the gas that is evacuated from the vacuum-providing openings 16 must pass through holes 336a-336p of the bottom rubber layer 28, these holes 336a-336p may be thought of and referred to as the “gas outlets” of the six layer assembly. Tunnel members 11a, 11b and its respective gas channels 15a, 15b are depicted in dashed outline in FIG. 5 (understood as being disposed beneath the bottom rubber layer 28 in the top view of same) so as to illustrate the orientation of the gas channels 15a, 15b with respect to the holes 336a-336p.

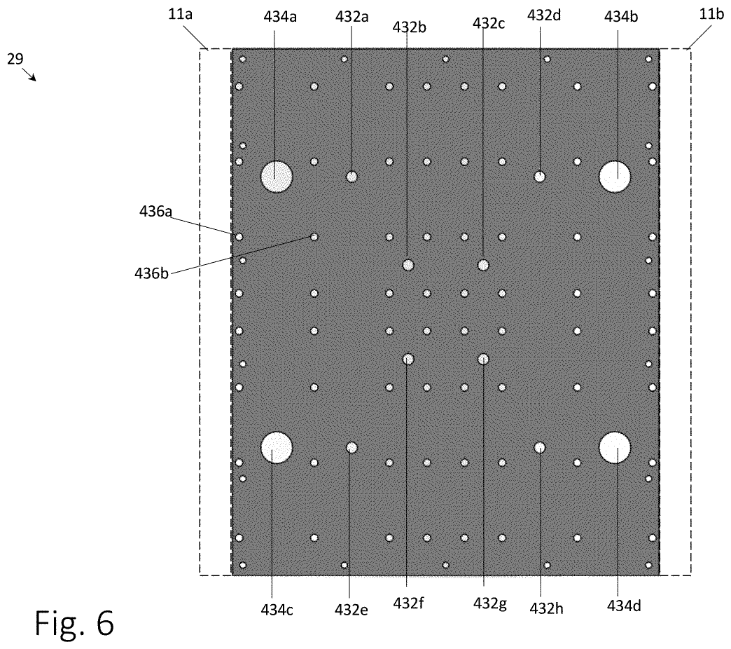

FIG. 6 depicts the top view of bottom holder plate 29. Bottom holder plate 29, may have a plurality of holes, including holes (two of which are labeled as 436a, 336b) for the through hole pins. The plurality of holes may also include holes (eight of which are labeled as 432a-432h) to accommodate the lift pins. The plurality of holes may also include holes (four of which are labeled as 434a-434d) to accommodate the ceramic plate adjustment pins. The dimensions of the bottom holder plate 29 may differ from that of the top holder plate 22 to accommodate the tunnel members 11a, 11b. For example, the width of the bottom holder plate 29 may be narrower than width of the top holder plate 22 (as may be apparent by comparing FIGS. 2 and 6). The bottom holder plate 29 may be disposed between the tunnel members 11a, 11b (depicted in dashed outline).

FIG. 7 depicts a zoomed-in portion of the vacuum chuck 100 labeled as IV in FIG. 1c. FIG. 7 depicts a through hole pin 44 which has an important role in the vacuum chuck 100. First, it contains vertical sections 41 of the gas conduit that pass the vacuum from the vacuum distribution plate 26 to the ceramic plate 10 and enables suction to be created at the retaining surface 12. Second, it provides structural resiliency that minimizes the bending of the ceramic plate 10 when vacuum is applied. A strong vacuum can cause some bending of the ceramic surface 10 that in turn can cause a reduction in the planar nature of the retaining surface 12. To reduce such bending, the through hole pin 44 secures the ceramic plate 10 to a metal stopper 48 that is disposed between the ceramic plate 10 and the top holder plate 22. A first surface of the metal stopper 48 may contact the ceramic plate 10 and a second surface of the metal stopper 48 may contact the top holder plate 22. A rubber O-ring 50 may be present to absorb some of the stresses in the junction between the ceramic plate 10, through hole pin 44 and metal stopper 48.

Vacuum-providing opening 16 is also shown in greater detail in FIG. 7. A rim 104 of the vacuum-providing opening 16 may be shaped to accommodate the spherical shape of a vacuum stopper, allowing for a vacuum stopper to form a gas tight seal of vacuum-providing opening 16.

In one embodiment, the vacuum chuck system includes a component placing module that enables an operator to position a component on the retaining surface 12 with very good spatial accuracy. The positional accuracy at which the component is placed on the retaining surface 12 is important to allow for the proper operation of the vacuum chuck 100. As previously described, the top side of the retaining surface 12 is composed of openings 16 and depressions 14. Therefore, it is important to be able to accurately position the component on the retaining surface 12 in order to completely cover any depressions 14 that have an active suction. The component placing module 60 is designed for that end.

FIGS. 8a-8c depict several views of the component placing module 60 in order to illustrate its construction and operation. In a first step of operating the component placing module 60, an operator (or a mechanical arm) positions a component 66 on the component support member 62 of the component placing module 60. For ease of depiction, the outline 66 of the component is drawn in dashed lined, instead of the component itself. Component support member 62 may have two cutouts 64 in its surface to allow for the insertion of the lift pins of the vacuum chuck 100 (neither the lift pins nor the vacuum chuck are depicted in FIG. 8a). The component placing module 60 may have two alignments arms, an x-arm 68 to translate the component 66 in a first horizontal direction and a y-arm 70 to translate the component 66 in a second direction perpendicular to the first direction. By an operator's hands or through the use of arms 68 and 70, a corner 65 of the component 66 may be oriented at a location on the component support member 62 for which the component 66 is in contact with both of the arms 68 and 70.

FIG. 8b depicts a top perspective view of component placing module 60, in which screw drive mechanisms are more easily visible. Screw drive mechanism 72 may translate the x-arm 68 in the first direction and screw drive mechanism 74 may translate the y-arm 70 in the second direction perpendicular to the first direction.

FIG. 8c depicts a top perspective view of the component placing module 60, in which the component support member 62 positions the component 66 above vacuum chuck 100. Again, for ease of depiction, the outline of the vacuum chuck 100 has been drawn in dashed line, instead of the vacuum chuck itself. To remove the component 66 from the component placing module 60, lift pins (not shown in FIG. 8c) are extended from the vacuum chuck 100 (in the z-direction) through cutouts 64 and gently elevate the component 66 above the component support member 62. The component support member 62 is then retracted, leaving the component 66 resting on the lift pins of the vacuum chuck 100.

Since the component placing module 60 has high spatial precision, it is possible to place of the component 66 on the vacuum chuck 100 in a completely automated fashion. The only user input needed are the dimensions of the component 66. The optimized placement of the component 66 on the retaining surface 12 (in turn dictating which vacuum providing openings need to be sealed and left open) can be calculated directly from the layout of the depression 14 and openings 16, as well as the movement of the component support member 62. By such automated placement, human error can be minimized, in turn increasing the robustness of the system.

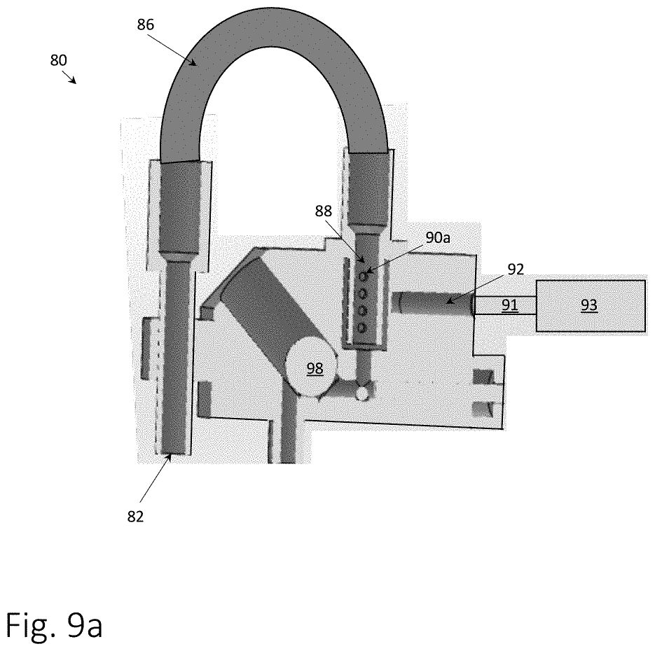

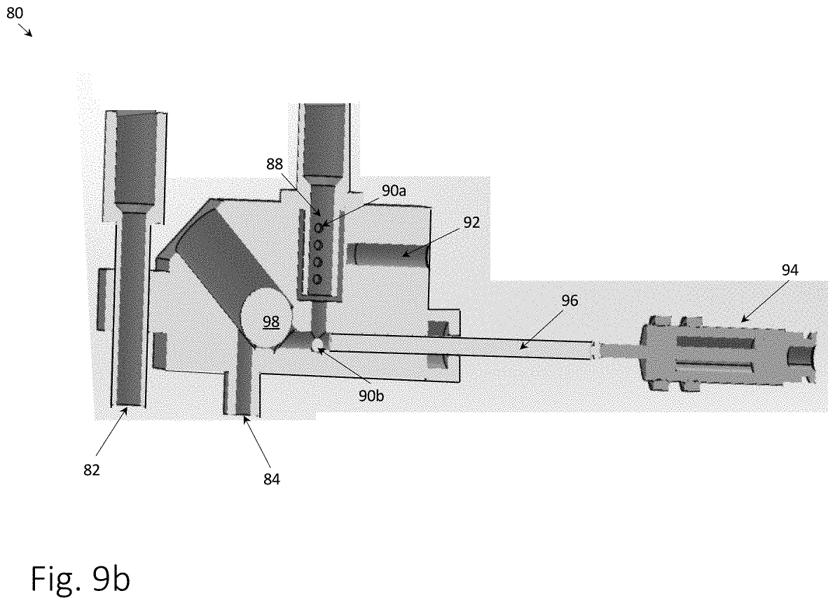

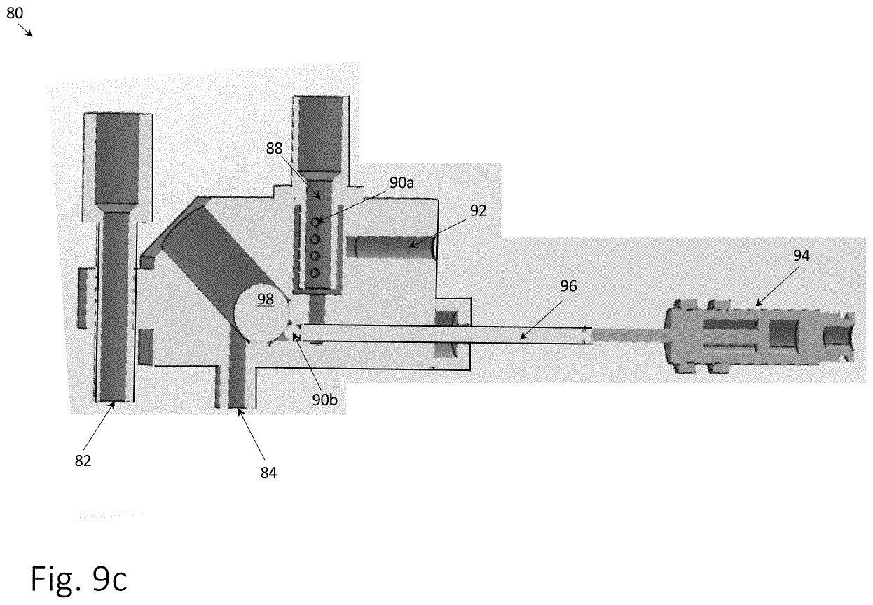

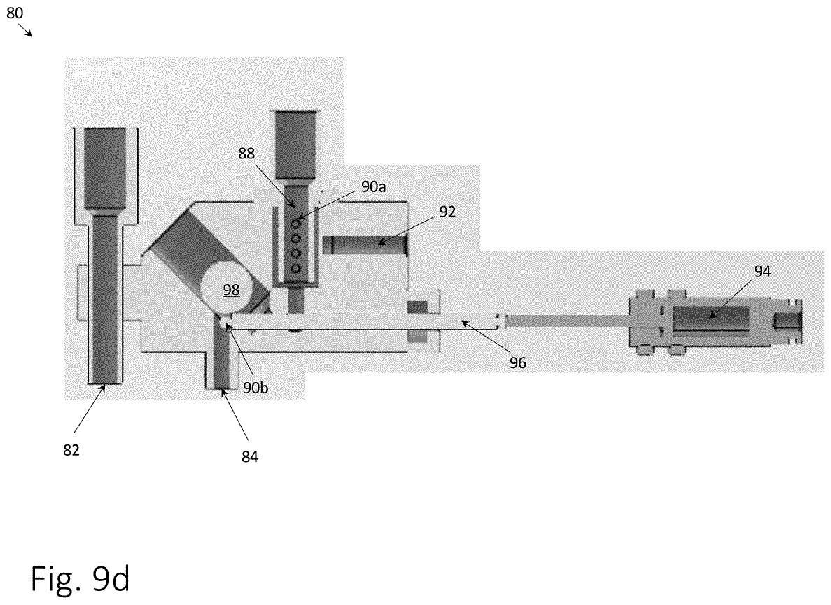

In one embodiment, the vacuum chuck system also includes a vacuum stopper collection and dispensing module 80. FIG. 9a depicts the vacuum stopper collection and dispensing module 80 configured in the collection mode. The module 80 includes a collection opening 82 for receiving one or more vacuum stoppers and a magazine 88 configured to store the one or more vacuum stoppers 90a received from the first collection opening 82. In the collection mode, a tube 86 may connect the collection opening 82 to the magazine 88 and such tube 86 may be removed from the module 80 in the dispensing mode (as shown in FIGS. 9b-9d). In the collection mode, a sealing member 98 may also be biased toward a first end of the magazine 88 (e.g., by gravity) so as to seal the first end of the magazine 88 in a gas-tight manner. The position of the sealing member 98 in FIG. 9a may be referred to as a sealing position. A vacuum pump 93 may be connected to vacuum port 92 of the module 80 via tubing 91. When the vacuum pump 93 is turned on, a suction is created at collection opening 82, causing any objects (e.g., vacuum stoppers) with a dimension less than the dimension of the collection opening 82 to be drawn into the collection opening 82 and collected in magazine 88.

FIGS. 9b-9d depict the vacuum stopper collection and dispensing module 80 configured in the dispensing mode. In the dispensing mode, a shaft 96 may be translated from the retracted position shown in FIG. 9b, to the semi-extended position shown in FIG. 9c and to the fully extended position shown in FIG. 9d in order to dispense a vacuum stopper 90b from the magazine 88 through the dispensing opening 84. A shaft driver 94 may be used to push and pull the shaft 96 during the dispensing operation. FIG. 9c depicts the position of the shaft 96 at which the vacuum stopper 90b just starts to push against the sealing member 98. Additional extension of the shaft 96 causes the sealing member 98 to be translated from the sealing position illustrated in FIGS. 9a-9c to the dispensing position illustrated in FIG. 9d. In the dispensing position, the shaft 96 and vacuum stopper 90b are able to pass underneath the sealing member 98. While not depicted, it is understood that after the vacuum stopper 90b reaches the position shown in FIG. 9d, gravity will cause the vacuum stopper 90b to fall though the dispensing opening 84. After the shaft 96 is retracted by the shaft driver 94, additional vacuum stoppers may be dispensed in the similar manner as depicted in FIGS. 9b-9d. In one embodiment, module 80 may be placed on a motorized Z axis to enable accurate placement and collection of the vacuum stoppers.

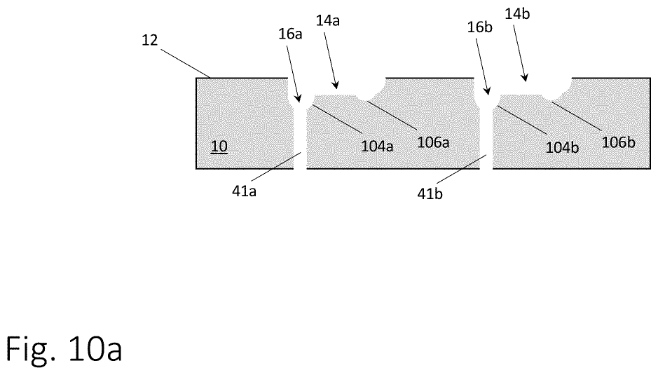

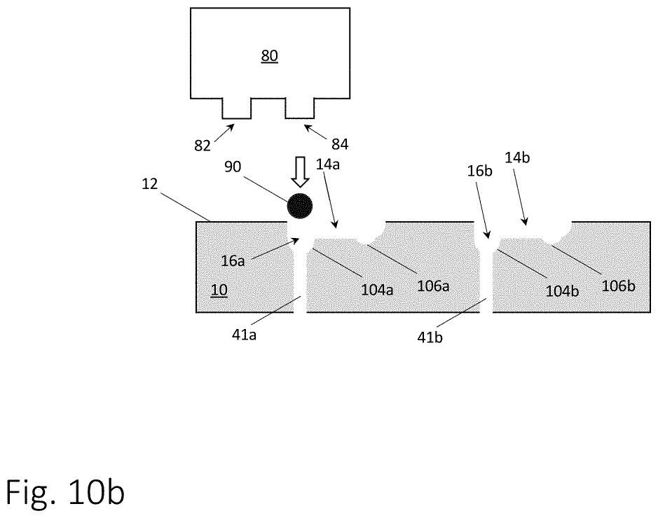

FIGS. 10a-10c depict a sequence of views illustrating a process of restricting the vacuum area of the retaining surface 12 in order to secure a PC board with more limited dimensions to the retaining surface 12. More specifically, FIG. 10a depicts a cross-sectional view of the ceramic plate 10 along line V-V of FIG. 1a, in which depressions 14a, 14b and openings 16a, 16b are shown in greater detail. Depression 14a may include an opening 16a at one end and an indentation 106a at the other end for holding the vacuum stopper 90 when the opening 16a is to be left open. It is noted that FIG. 10a has been simplified to show only a gas passageway 41a connected to the opening 16a instead of the complete details which would include the through hole pin 44 depicted in FIG. 7. In a similar manner, depression 14b may include an opening 16b at one end and an indentation 106b at the other end. Opening 16b may be connected to gas passageway 41b.

FIG. 10b depicts the dispensing of a vacuum stopper 90 from the collection and dispensing module 80 in order to seal opening 16a. In preparation for the dispensing, the dispensing opening 84 of the vacuum stopper collection and dispensing module 80 is first positioned directly above opening 16a of the ceramic plate 10. After the positioning, vacuum stopper 90 may be dispensed from dispensing opening 84, before settling onto and resting on the rim 104a of opening 16a. As described above, the rim 104a of the opening 16a may be shaped to accommodate the spherical shape of the vacuum stopper 90, allowing the vacuum stopper 90 to form a gas-tight seal of opening 16a.

FIG. 10c depicts a vacuum stopper 90 decoupling a first unutilized (uncovered) region of the retaining surface 12 from a vacuum pump (not depicted), and a PC board 108a being secured to a second region of the retaining surface 12 by way of the suction created within depression 14b by the vacuum pump.

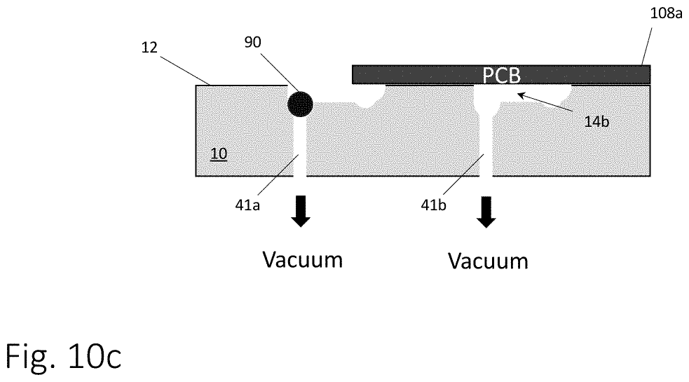

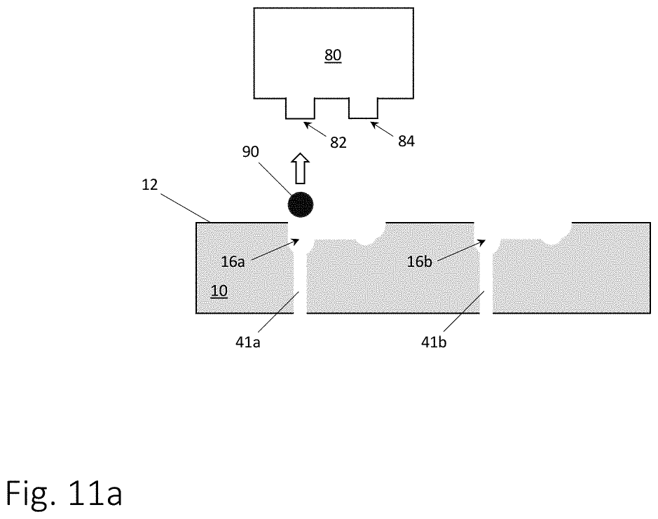

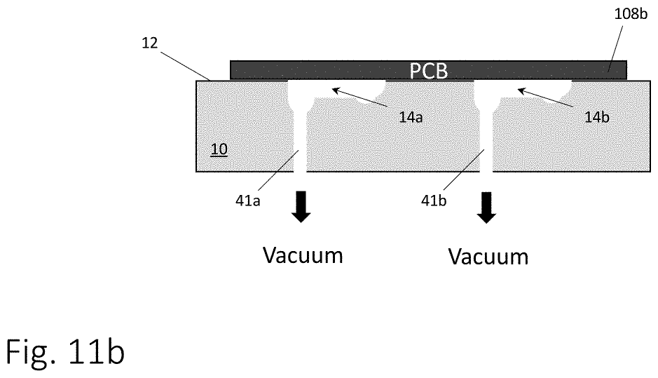

FIGS. 11a-11b depict a sequence of views illustrating a process of increasing the vacuum area of the retaining surface 12 in order to secure a PC board with larger dimensions to the retaining surface 12. More specifically, FIG. 11 a depicts the collection of the vacuum stopper 90 in order to unblock opening 16a. In preparation for the collection, the collection opening 82 of the vacuum stopper collection and dispensing module 80 is first positioned directly above opening 16a of the ceramic plate 10. After the positioning, the vacuum stopper 90 may be drawn into the collection opening 82 by a suction force.

FIG. 11b depicts a PC board 108b with larger dimensions than PC board 108a being secured to the retaining surface 12. The PC board 108b completely seals both depressions 14a and 14b, and the vacuum generated within depressions 14a and 14b is used to secure the PC board 108b to the retaining surface 12.

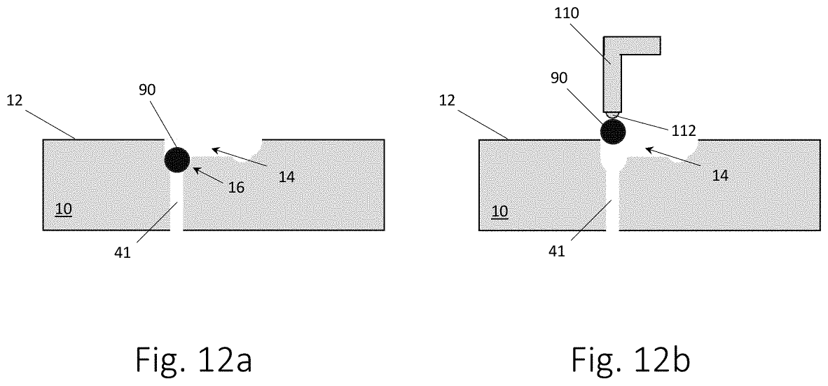

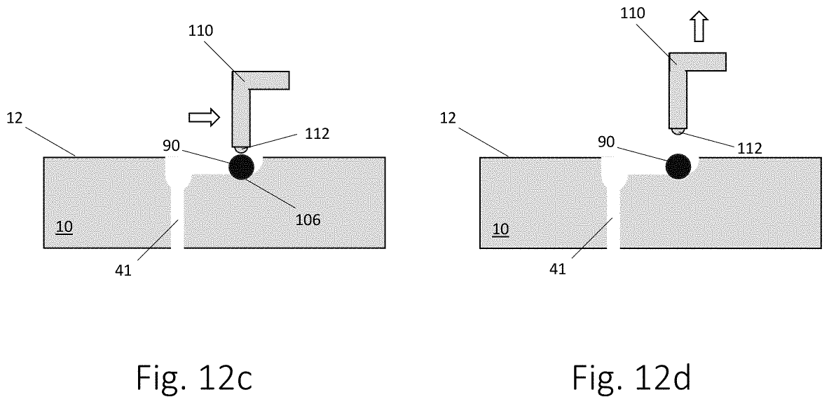

FIGS. 12a-12d depict a sequence of views in which an electromagnet 112 is used to move a vacuum stopper 90 from a first blocking position to a second non-blocking position in a depression 14. Such an embodiment differs from the previously described embodiments in FIG. 10a-10c and 11a-11b in that the vacuum stopper 90, when not in the blocking position, rests on the surface of ceramic plate 10 rather than being stored within the magazine 88 of the vacuum stopper collection and dispensing module 80.

FIG. 12a depicts the vacuum stopper 90 in a blocking position, sealing opening 16 and one end of gas passageway 41. As depicted in FIG. 12b, an electromagnet 112 attached to an end of a robotic arm 110 is used to remove the vacuum stopper 90 from the opening 16. In the embodiment of FIGS. 12a-12d, it is understood that the vacuum stopper 90 may include materials that are attracted to an electromagnet, such as iron, cobalt and nickel, as well as alloys composed of these ferromagnetic metals. As depicted in FIG. 12c, the robotic arm 110 is used to place the vacuum stopper 90 in a non-blocking position (e.g., with a bottom portion of the vacuum stopper 90 supported on indentation 106). Finally, as depicted in FIG. 12d, the electromagnet 12 may be turned off so as to allow the vacuum stopper 90 to separate from the electromagnet 112.

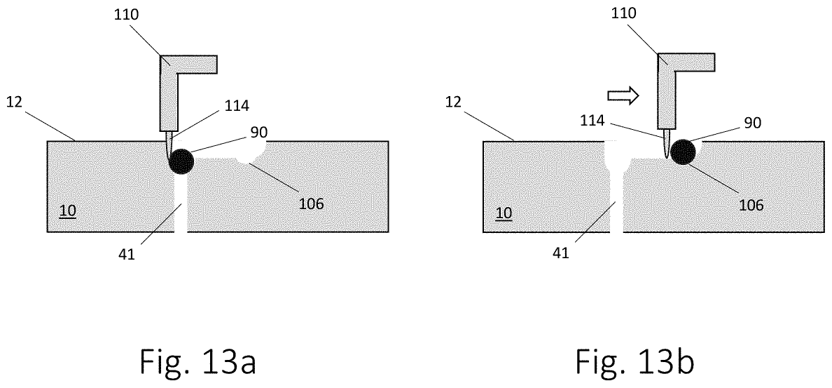

FIGS. 13a-13b depict a sequence of views in which a robotic arm 110 is used to move a vacuum stopper 90 from a first blocking position to a second non-blocking position in a depression 14. FIG. 13a depicts the vacuum stopper 90 in a blocking position, sealing opening 16 and one end of gas passageway 41. An appendage or projecting portion 114 of the robotic arm 110 may be first placed in contact with the vacuum stopper 90. The robotic arm 110 is then horizontally translated so as to position the vacuum stopper 90 in a non-blocking position (e.g., with a bottom portion of the vacuum stopper 90 supported on indentation 106).

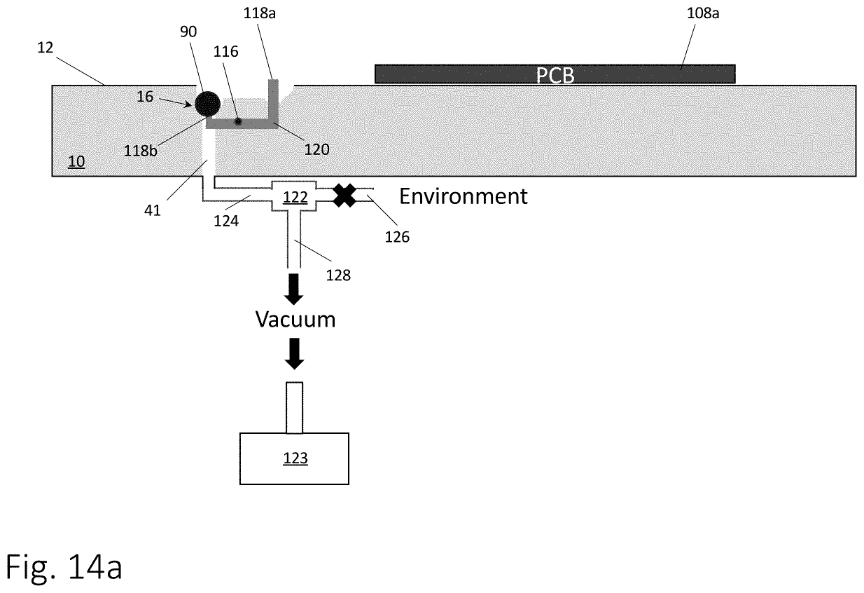

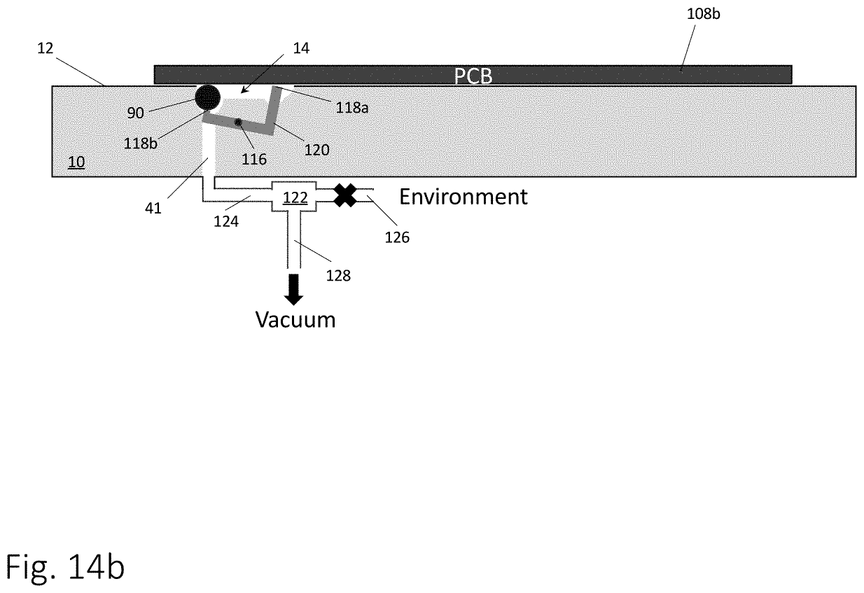

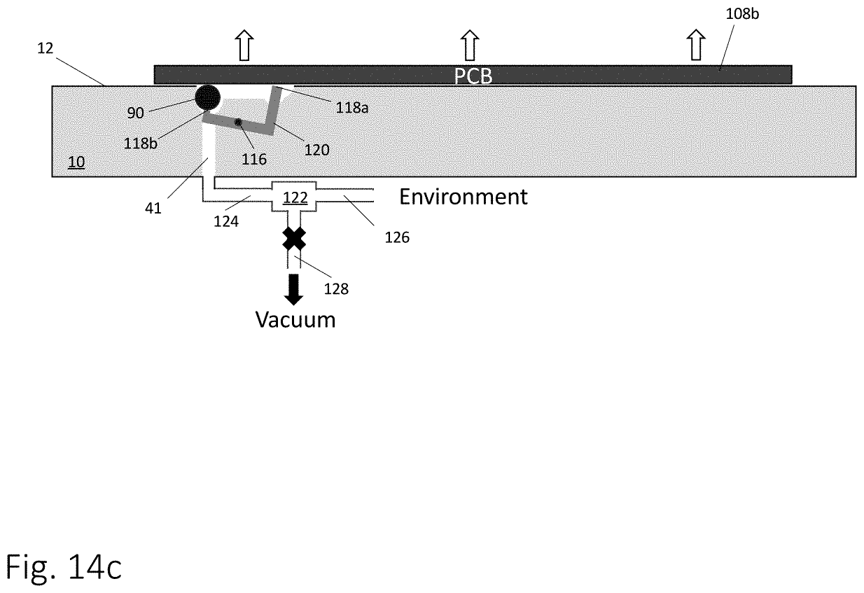

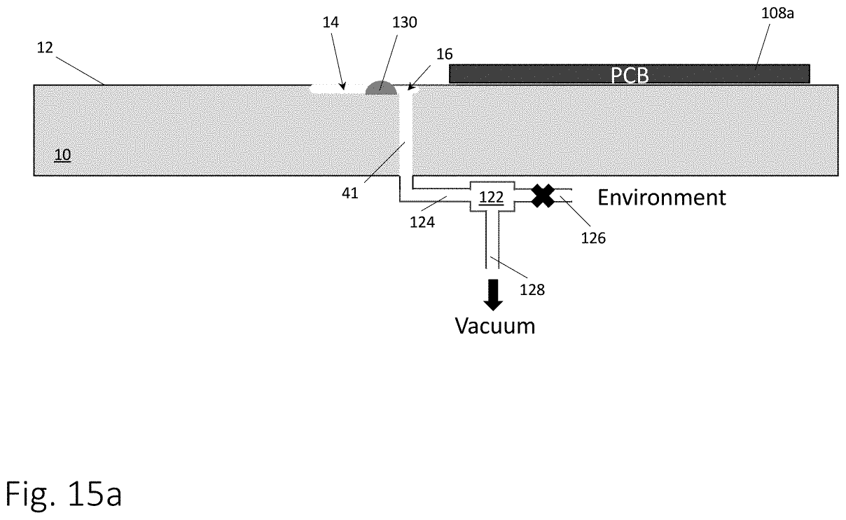

FIGS. 14a-14c depict the operation of a lever mechanism for controllably sealing or unsealing an opening 16 of the retaining surface 12. The lever mechanism may include a lever arm 120 that rotates (or pivots) about pivot point 116. The steady state configuration of the lever mechanism is depicted in FIG. 14a in which vacuum stopper 90 seals opening 16. A first end 118a of the lever arm 120 protrudes above the retaining surface 12, while a second end 118b touches vacuum stopper 90. The activated state of the lever mechanism is depicted in FIG. 14b in which the first end 118a has been depressed by PC board 108b. The force imparted on the first end 118a causes the lever arm 120 to rotate about pivot point 116. The rotation in turn causes the second end 118b to dislodge the vacuum stopper 90 from the opening 16, effectively unsealing the opening 16.

The application of the lever mechanism within the context of the vacuum chuck 100 will now be explained. In FIG. 14a, with the lever mechanism in the steady state configuration and opening 16 sealed by the vacuum stopper 90, PC board 108a (with more limited dimensions) may be secured to the retaining surface 12 via a suction provided by vacuum pump 123. It is understood that depressions (not shown in the cross section of FIG. 14a) are covered by the bottom surface of PC board 108a, and the vacuum within these depressions secures the PC board 108a to the retaining surface 12.

A three-way valve 122 may be present to switch the pressure within the gas passageway 41 between sub-atmospheric pressure (i.e., vacuum) and atmospheric pressure. The three-way valve 122 may be connected to three conduits 124, 126 and 128. A first one of the conduits 124 may be fluidly coupled to gas passageway 41; a second one of the conduits 128 may be fluidly coupled to vacuum pump 123; and a third one of the conduits 126 may be fluidly coupled to the “environment” (i.e., the surrounding of the vacuum chuck 100 with atmospheric pressure). Again, it is understood that FIG. 14a has been simplified for ease of depiction, with the first conduit 124 directly coupled to the gas passageway 41 of the ceramic plate 10. In practice, there may be other layers (rubber layer, vacuum distribution plate, . . . ) through which the gas passageway 41 may traverse before the gas passageway 41 meets the first conduit 124.

In the setup of FIG. 14a, conduits 124 and 128 are open, while conduit 126 is closed, allowing PC board 108a to be secured to the retaining surface 12. The setup of FIG. 14b is similar to that of FIG. 14a, except that PC board 108b has dimensions that are larger than that of PC board 108a. PC board 108b completely covers depression 14. Further, the lever mechanism causes the opening 16 to be unsealed, allowing vacuum to propagate into depression 14 which creates a suction that secures the PC board 108b to the retaining surface 12.

FIG. 14c depicts a state of the vacuum chuck 100, in which the vacuum is released and the gas passageway 41 is coupled to the environment. In such a state, PC board 108b may be removed from the retaining surface 12. More specifically, conduits 124 and 126 are open, allowing gas passageway 41 to be coupled to the environment, and conduit 128 is closed to decouple the vacuum pump from the gas passageway 41.

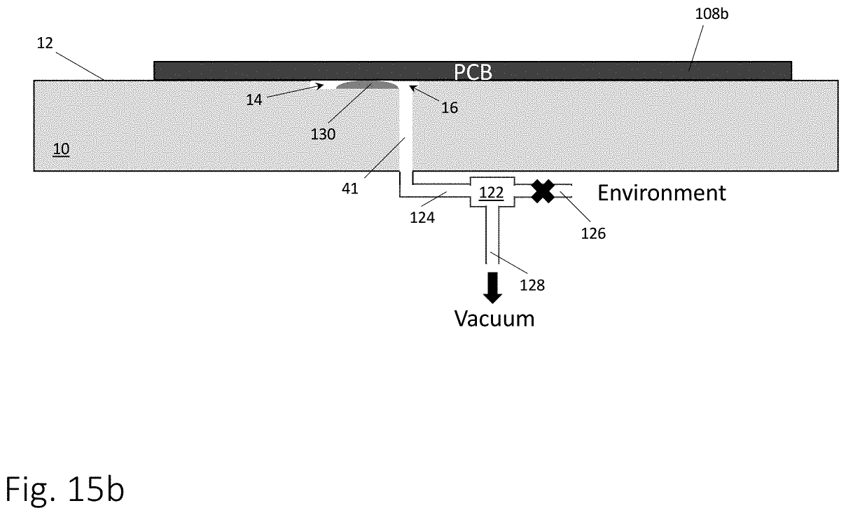

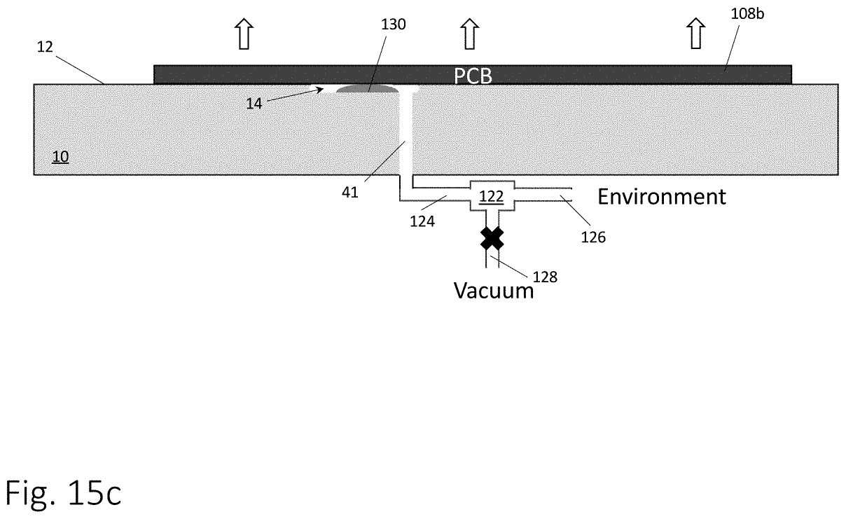

FIGS. 15a-15c depict the operation of a diaphragm mechanism 130 for controllably sealing or unsealing an opening 16 of the retaining surface 12. The steady state configuration of the diaphragm mechanism 130 is depicted in FIG. 15a in which the diaphragm mechanism 130 seals opening 16. The depressed state of the diaphragm mechanism 130 is depicted in FIG. 15b in which the diaphragm mechanism 130 has been flattened by PC board 108b, causing opening 16 to be unsealed. It is noted that in contrast to the previously described embodiments, the diaphragm mechanism 130 itself is the vacuum stopper and thus no spherical ball-type stopper is needed. Further, it is noted that the shape of the opening 16 may differ in the present embodiment as it is no longer the case that the rim of opening 16 needs to support a spherical ball-type stopper. Diaphragm mechanism 130 may be made using a readily deformable material, such that the weight of the PC board 108b is sufficient to flatten and deform the diaphragm mechanism 130.

The application of the diaphragm mechanism 130 within the context of the vacuum chuck 100 will now be explained. As shown in FIG. 15a, with the opening 16 sealed by diaphragm 130, PC board 108a with more limited dimensions can be secured to the retaining surface 12. It is understood that the vacuum from the vacuum pump may be provided to depressions (not shown in FIG. 15a) which contact an underside of PC board 108a.

FIG. 15b depicts a PC board 108b with larger dimensions than PC board 108a being secured to the retaining surface 12. PC board 108b completely covers depression 14. PC board 108b additionally depresses diaphragm 130, allowing the vacuum to enter within depression 14, in turn securing PC board 108b to the retaining surface 12.

FIG. 15c depicts the PC board 108b being removed from the retaining surface 12. Prior to its removal, gas passageway 41 is connected to the environment through the three-way valve 122, allowing depression 14 to normalize to atmospheric pressure.

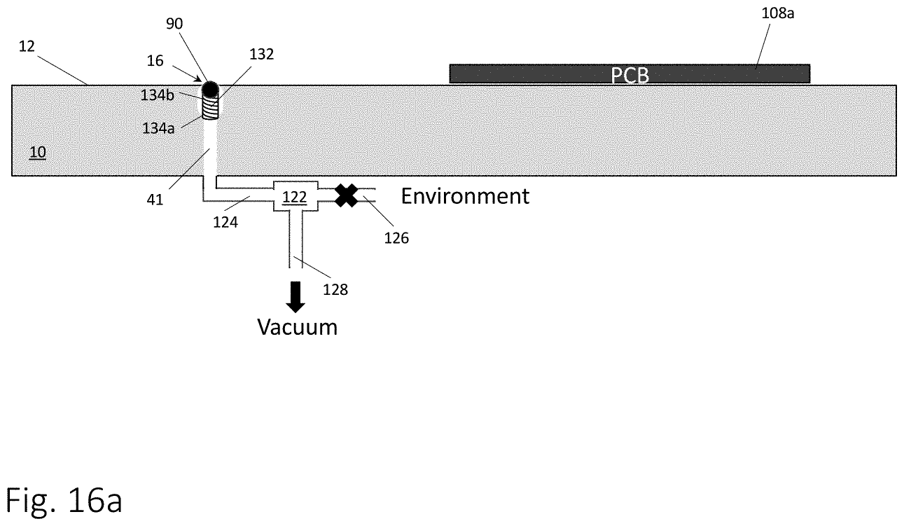

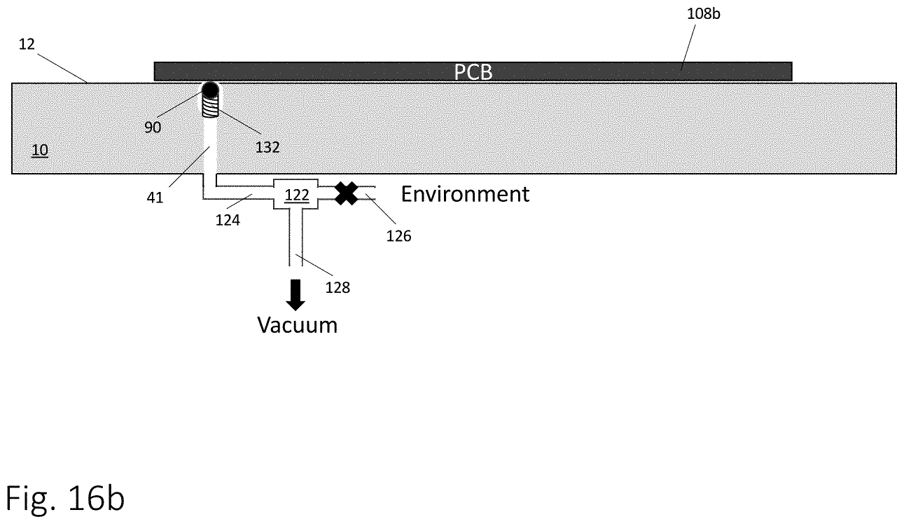

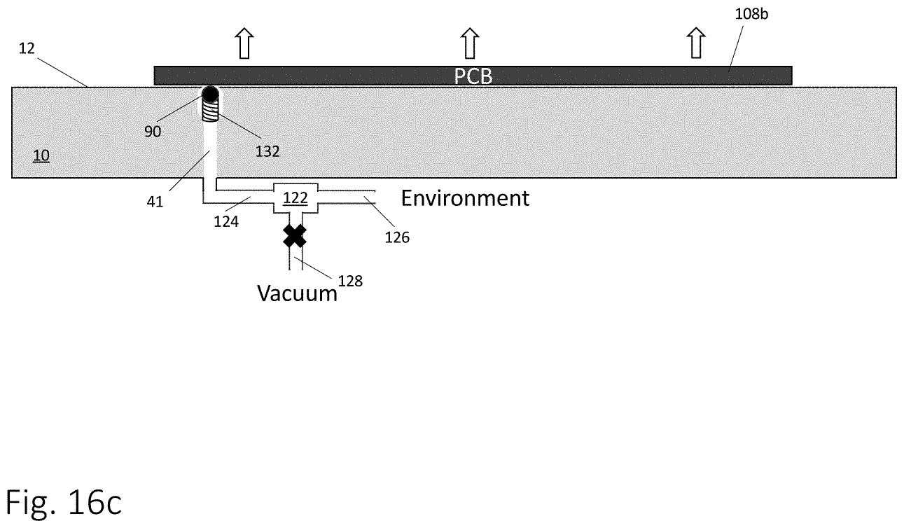

FIGS. 16a-16c depict the operation of a spring-loaded ball mechanism for controllably sealing or unsealing an opening 16 of the retaining surface 12. The steady state configuration of the spring-loaded ball mechanism is depicted in FIG. 16a in which the vacuum stopper 90 is biased towards opening 16 (thereby sealing the opening 16) by a spring 132. A portion of vacuum stopper 90 protrudes out of the opening 16 above the plane of the retaining surface 12. A first end 134a of the spring 132 is fixed in place (i.e., pushes against a constriction in gas passageway 41), whereas a second end 134b of the spring 132 that engages the vacuum stopper 90 is moveable in the vertical (z) direction. The compressed state of the spring-loaded ball mechanism is depicted in FIG. 16b in which the vacuum stopper 90 is biased away from the opening 16 (thereby unsealing the opening 16) by PC board 108b. The tension of the spring 132 is chosen so that the downward force of the PC board 108b on the vacuum stopper 90 (caused by gravity acting on the PC board 108b) is greater than the upward force of the spring 132 acting on the vacuum stopper 90, allowing the weight of the PC board 108b to compress the spring 132.

The application of the spring-loaded ball mechanism within the context of the vacuum chuck 100 will now be explained. As depicted in FIG. 16a, with opening 16 sealed by the spring-loaded ball mechanism, PC board 108a with more limited dimensions can be secured to the retaining surface 12. It is understood that the vacuum from the vacuum pump may be provided to openings (not shown in FIG. 16a) which contact an underside of PC board 108a.

FIG. 16b depicts a PC board 108b with larger dimensions than PC board 108a being secured to the retaining surface 12. PC board 108b pushes down on vacuum stopper 90, unsealing opening 16. The vacuum within gas passageway 41 is able to contact an underside of the PC board 108b, in turn securing PC board 108b to the retaining surface 12

FIG. 16c depicts the PC board 108b being removed from the retaining surface 12. Prior to its removal, the gas passageway 41 is connected to the environment through the three-way valve 122, allowing the gas passageway 41 to normalize to atmospheric pressure.

It is understood that many of the components described above may be under the control of a computing system. For example, the operation of the vacuum chuck 100 may be controlled by a computing system (including the operation of lift pins 30a-30h, and vacuum pump 123). In addition, the operation of the component placing module 60 may be controlled by a computing system (including the operation of the x-arm 68, the y-arm 70 and the component supporting member 62). In addition, the operation of the vacuum stopper collection and dispensing module 80 may be controlled by a computing system (including the positioning of the vacuum stopper collection and dispensing module 80, the operation of the vacuum pump 93 and the operation of the shaft driver 94).

FIG. 17 provides an example of a computer system 200 that may be representative of any of the computing systems discussed herein. Note, not all of the various computer systems have all of the features of computer system 200. For example, certain ones of the computer systems discussed above may not include a display inasmuch as the display function may be provided by a client computer communicatively coupled to the computer system or a display function may be unnecessary. Such details are not critical to the present invention.

Computer system 200 includes a bus 202 or other communication mechanism for communicating information, and a processor 204 (e.g., a microcontroller, an ASIC, a CPU, etc.) coupled with the bus 202 for processing information. Computer system 200 also includes a main memory 206, such as a random access memory (RAM) or other dynamic storage device, coupled to the bus 202 for storing information and instructions to be executed by processor 204. Main memory 206 also may be used for storing temporary variables or other intermediate information during execution of instructions to be executed by processor 204. Computer system 200 further includes a read only memory (ROM) 208 or other static storage device coupled to the bus 202 for storing static information and instructions for the processor 204. A storage device 220, for example a hard disk, flash memory-based storage medium, or other storage medium from which processor 204 can read, is provided and coupled to the bus 202 for storing information and instructions (e.g., operating systems, applications programs and the like).

Computer system 200 may be coupled via the bus 202 to a display 212, such as a flat panel display, for displaying information to a computer user. An input device 214, such as a keyboard including alphanumeric and other keys, may be coupled to the bus 202 for communicating information and command selections to the processor 204. Another type of user input device is cursor control device 216, such as a mouse, a trackpad, or similar input device for communicating direction information and command selections to processor 204 and for controlling cursor movement on the display 212. Other user interface devices, such as microphones, speakers, etc. are not shown in detail but may be involved with the receipt of user input and/or presentation of output.

The processes referred to herein may be implemented by processor 204 executing appropriate sequences of computer-readable instructions contained in main memory 206. Such instructions may be read into main memory 206 from another computer-readable medium, such as storage device 210, and execution of the sequences of instructions contained in the main memory 206 causes the processor 204 to perform the associated actions. In alternative embodiments, hard-wired circuitry or firmware-controlled processing units may be used in place of or in combination with processor 204 and its associated computer software instructions to implement the invention. The computer-readable instructions may be rendered in any computer language.

In general, all of the above process descriptions are meant to encompass any series of logical steps performed in a sequence to accomplish a given purpose, which is the hallmark of any computer-executable application. Unless specifically stated otherwise, it should be appreciated that throughout the description of the present invention, use of terms such as “processing”, “computing”, “calculating”, “determining”, “displaying”, “receiving”, “transmitting” or the like, refer to the action and processes of an appropriately programmed computer system, such as computer system 200 or similar electronic computing device, that manipulates and transforms data represented as physical (electronic) quantities within its registers and memories into other data similarly represented as physical quantities within its memories or registers or other such information storage, transmission or display devices.

Computer system 200 also includes a communication interface 218 coupled to the bus 202. Communication interface 218 may provide a two-way data communication channel with a computer network, which provides connectivity to and among the various computer systems discussed above. For example, communication interface 218 may be a local area network (LAN) card to provide a data communication connection to a compatible LAN, which itself is communicatively coupled to the Internet through one or more Internet service provider networks. The precise details of such communication paths are not critical to the present invention. What is important is that computer system 200 can send and receive messages and data through the communication interface 218 and in that way communicate with hosts accessible via the Internet.

Thus, a variable area vacuum chuck system and its operation has been described. Many other embodiments will be apparent to those of skill in the art upon reviewing the above description. The scope of the invention should, therefore, be determined with reference to the appended claims, along with the full scope of equivalents to which such claims are entitled.

What is claimed is:

1. A vacuum chuck system, comprising a vacuum chuck that comprises:
a retaining surface with a plurality of depressions and a plurality of openings, each of the openings being disposed on a bottom surface of one of the depressions and fluidly coupled to a first vacuum pump; and
a first vacuum stopper disposed within a first one of the depressions and resting on a rim of a first one of the openings, the first vacuum stopper decoupling a first region of the retaining surface from the first vacuum pump.

2. The vacuum chuck system of claim 1, wherein the vacuum chuck further comprises:
a ceramic plate that forms the retaining surface;
a first rubber layer with a first plurality of through holes, each fluidly coupled to one of the openings of the retaining surface; and
a vacuum distribution plate comprising a plurality of gas distribution channels that extend within the vacuum distribution plate in a direction parallel to an extent of the vacuum distribution plate, each of the gas distribution channels being fluidly coupled to one or more of the first plurality of through holes,
wherein the first rubber layer is disposed between the ceramic plate and the vacuum distribution plate.

3. The vacuum chuck system of claim 2, wherein the vacuum distribution plate comprises a metal material.

4. The vacuum chuck system of claim 2, wherein the vacuum chuck further comprises a plurality of pins that are translatable in a direction perpendicular to an extent of the ceramic plate, wherein in a retracted position, an upper extent of the plurality of pins is located within the vacuum chuck, and wherein an extended position, the upper extent of the plurality of pins protrudes from the retaining surface of the vacuum chuck.

5. The vacuum chuck system of claim 2, wherein the vacuum chuck further comprises a plurality of pins that are fixed in placed relative to the ceramic plate, each of the pins configured to secure the ceramic plate, the first rubber layer and the vacuum distribution plate to one another.

6. The vacuum chuck system of claim 5, further comprising a plurality of metal stoppers, wherein for each of the metal stoppers, a first surface of the metal stopper contacts the ceramic plate and a second surface of the metal stopper contacts a first holder plate.

7. The vacuum chuck system of claim 6, further comprising a plurality of O-rings, wherein each of the O-rings is disposed about a circumferential portion of each of the pins, and is sandwiched between the ceramic plate and a portion of each of the metal stoppers.

8. The vacuum chuck system of claim 5, wherein each of the pins comprises a gas conduit that fluidly couples one of the openings with the first vacuum pump.

9. The vacuum chuck system of claim 2, wherein the vacuum chuck further comprises:
a second rubber layer with a second plurality of through holes, each fluidly coupled to one of the gas distribution channels of the vacuum distribution plate,
wherein the vacuum distribution plate is disposed between the first rubber layer and the second rubber layer.

10. The vacuum chuck system of claim 9, wherein the vacuum chuck further comprises:
a second holder plate with a third plurality of through holes,
wherein the second rubber layer is disposed between the vacuum distribution plate and the second holder plate.

11. The vacuum chuck system of claim 1, further comprising a vacuum stopper collection and dispensing module that comprises:
a collection opening for receiving one or more vacuum stoppers from the plurality of depressions;
a magazine configured to receive and store the one or more vacuum stoppers from the first collection opening; and
a dispensing opening for dispensing the one or more vacuum stoppers from the magazine into one or more of the depressions of the retaining surface.

12. The vacuum chuck system of claim 11, wherein the vacuum stopper collection and dispensing module further comprises:
a sealing member, wherein in a non-dispensing position, the sealing member is biased toward a first end of the magazine so as to seal the first end of the magazine in a gas-tight manner; and
a shaft configured to push one of the one or more vacuum stoppers from the magazine against the sealing member so as to move the sealing member into a dispensing position.

13. The vacuum chuck system of claim 11, wherein the vacuum stopper collection and dispensing module further comprises a second vacuum pump configured to generate a vacuum adjacent to the collection opening for transporting the one or more vacuum stoppers from the plurality of depressions into the first collection opening.

14. The vacuum chuck system of claim 1, further comprising an electromagnet configured to generate a magnetic field for transporting the first vacuum stopper from a first position within the first depression to a second position within the first depression.

15. The vacuum chuck system of claim 1, further comprising a robotic arm for transporting the first vacuum stopper from a first position within the first depression to a second position within the first depression.

16. A method of operating a vacuum chuck, the method comprising:
placing a vacuum stopper on a rim of an opening of a retaining surface of the vacuum chuck, the opening being fluidly coupled to a vacuum pump and being disposed on a bottom surface of a depression of the retaining surface, the placement of the vacuum stopper on the rim causing a first region of the retaining surface of the vacuum chuck to be fluidly decoupled from the vacuum pump;
positioning an object on a second region of the retaining surface; and
applying a vacuum, by the vacuum pump, to the second region of the retaining surface so as to secure the object to the second region of the retaining surface, the second region being distinct from the first region.

17. The method of claim 16, wherein placing the vacuum stopper on the rim comprises moving the vacuum stopper from a first position within the depression to a second position within the depression, wherein the first position is remote from the rim, and the second position is at the rim.

18. The method of claim 16, wherein placing the vacuum stopper on the rim comprises positioning a dispensing opening of a vacuum stopper dispensing system above the depression of the retaining surface and dispensing the vacuum stopper from the dispensing opening of the dispensing system into the depression.

19. A method of operating a vacuum chuck, the method comprising:
removing a vacuum stopper from a rim of an opening of a retaining surface of the vacuum chuck, the opening being fluidly coupled to a first vacuum pump and being disposed on a bottom surface of a depression of the retaining surface, the removal of the vacuum stopper from the rim causing a first region of the retaining surface of the vacuum chuck to be fluidly coupled to the first vacuum pump;
positioning an object on the first region of the retaining surface; and
applying a vacuum, by the first vacuum pump, to the first region of the retaining surface so as to secure the object to the first region of the retaining surface.

20. The method of claim 19, wherein removing the vacuum stopper from the rim comprises moving the vacuum stopper from a first position within the depression to a second position within the depression, wherein the first position is at the rim, and the second position is away from the rim.
